(19) United States
(12) Patent Application Publication
(10) Pub. No.: US 2021/0402424 A1
(43) Pub. Date: Dec. 30, 2021

(54) SURFACE TREATMENT DEVICE

(71) Applicant: UNIVERSAL CIRCUIT BOARD EQUIPMENT CO., LTD., Dongguan (CN)

(72) Inventor: Takwo CHAN, Dongguan (CN)

(21) Appl. No.: 17/032,293

(22) Filed: Sep. 25, 2020

Related U.S. Application Data
(63) Continuation of application No. PCT/CN2020/107621, filed on Aug. 7, 2020.

(30) Foreign Application Priority Data
Jun. 30, 2020 (CN) 202010612375.9

(51) Int. Cl. B05B 16/00; B25J 11/00; B25J 9/10; B65G 19/02; H05K 3/26

(52) U.S. Cl. CPC B05B 16/90; B25J 11/0075; B25J 9/105; B65G 19/025; H05K 2203/1518; H05K 2203/0736; H05K 2203/0756; H05K 2203/0165; H05K 3/26

(57) ABSTRACT

Disclosed is a surface treatment device. The surface treatment device includes: a frame; a disc hanger; two support wheels for supporting the disk hanger; a rotation drive mechanism for driving the disk hanger supported on the two support wheels to rotate; a vertical spray rack for spraying liquid medicine on the circuit board on the disk hanger; and a lift mechanism for driving the vertical spray rack up and down.

### CROSS-REFERENCE TO RELATED APPLICATIONS

This application is a Continuation Application of PCT Application No. PCT/CN2020/107621, filed on Aug. 7, 2020, claims priority to Chinese Application No. 202010612375.9, filed on Jun. 30, 2020, entitled “SURFACE TREATMENT DEVICE”, the entire disclosure of which is incorporated herein by reference.

### TECHNICAL FIELD

The present disclosure relates to the technical field of circuit board processing device, in particular to a surface treatment device.

### BACKGROUND

The statements here only provide background information related to the present disclosure, and do not necessarily constitute prior art. When the circuit board is manufactured, it is generally necessary to use a surface treatment device to process the circuit board such as etching, stripping, and cleaning. When a surface of the circuit board is treated, a spray method is generally configured to spray liquid on the circuit board. At present, the spray method is divided into horizontal spray and vertical spray. Horizontal spray is to place the circuit board on a horizontal transfer line, and the spray pipe is arranged on a horizontal surface, and the nozzles on the spray pipe spray downward to the circuit board. The vertical spray is to set the circuit board vertically, and the spray pipe is arranged on a vertical surface, and the nozzle on the spray pipe sprays liquid medicine on the vertical circuit board. Due to the horizontal spray, the liquid medicine on the circuit board often cannot flow out in time, which will affect the processing accuracy; therefore, most of high-quality circuit boards are processed by the vertical spray. In order to make the liquid medicine cover the entire circuit board well, a rotation structure is generally provided in the surface treatment device that uses the vertical spray to drive the spray pipe to swing around a vertical axis. However, when the spray pipe swings around the vertical axis, the liquid medicine sprayed from the nozzle will be sprayed on the printed circuits obliquely, which will cause greater impact on sides of the circuits and affect the quality of the circuits.

### SUMMARY

The purpose of the embodiments of the present disclosure is to provide a surface treatment device, which aims to solve the problem in the related art that the spray pipe in the surface treatment device swings around the vertical axis, the side of the circuit will be subject to greater impact, which will affect the quality of the circuit.

In order to address the above technical problem, an aspect of the present disclosure provides a surface treatment device, including:

a frame;

a disc hanger for holding a circuit board;

two support wheels, supported on the frame, for supporting the disk hanger;

a rotation drive mechanism, supported on the frame, for driving the disk hanger supported on the two support wheels to rotate;

a vertical spray rack for spraying liquid medicine on the circuit board on the disk hanger; and

a lift mechanism, installed on the frame, for driving the vertical spray rack up and down;

the vertical spray rack is installed on the lift mechanism.

In an optional embodiment, the surface treatment device includes two vertical spray racks, the two vertical spray racks are provided side by side on both sides of the disk hanger; the lift mechanism includes lift rods connected to the two vertical spray racks respectively, a guide base for guiding the lift rod up and down, and a lift drive mechanism for driving the lift rod up and down; and the lift drive mechanism is installed on the frame, the guide base is installed on the frame, and the lift rod is slidably installed on the frame.

In an optional embodiment, the lift drive mechanism includes a push rod, a support for supporting a middle of the push rod, a rocker for driving one end of the push rod up and down, an eccentric wheel for driving the rocker to swing and a rotation drive assembly for driving the eccentric wheel to rotate; and both ends of the push rod are hinged and connected to the lift rods corresponding to the vertical spray racks, the rotation drive assembly is installed on the frame, the support is installed on the frame, and the middle of the push rod is hinged and connected to the support.

In an optional embodiment, the rotation drive assembly includes a rotation shaft for supporting the eccentric wheel, a drive shaft for driving the rotation shaft to rotate, a direction changer connecting the drive shaft with the rotation shaft, and a lift motor for driving the drive shaft to rotate; and the lift motor is installed on the frame, the drive shaft and the rotation shaft are rotatably installed on the frame.

In an optional embodiment, the lift drive mechanism includes a plurality of push rods and a plurality of supports for supporting the push rods; both ends of each of the push rods are hinged with the lift rods, and the lift rods at both ends of each of the push rods are respectively connected to the two vertical spray racks; and the lift drive mechanism further includes a connection rod, one end of each of the push rods is hinged with the connection rod, and the rocker is hinged with the connection rod.

In an optional embodiment, the lift mechanism further includes an elastic pusher for elastically pushing a corresponding lift rod upward; and an upper end of the elastic pusher is fixedly connected to the corresponding lift rod, and a lower end of the elastic pusher is supported on the frame.

In an optional embodiment, the surface treatment device further includes:

guide rails respectively provided on both sides of the two support wheels, for guiding transmission of the disk hanger;

a guide bar installed on the frame for supporting an upper side of the disk hanger; and

two lifters installed on the frame for driving the two support wheels up and down respectively; the two support wheels are respectively installed on the two lifters.

In an optional embodiment, each of the two lifters includes a support base slidably mounted on the frame, an eccentric cam for pushing the support base up and down, and a rotator for driving the eccentric cam to rotate; and the rotator is installed on the frame, and each of the support wheels is rotatably installed on the corresponding support base.

In an optional embodiment, each of the two lifters further includes an elastic puller for pulling the support base down, an upper end of the elastic puller is connected to the support base, and a lower end of the elastic puller is connected to the frame.

In an optional embodiment, the rotation drive mechanism includes a drive wheel for cooperating with the two support wheels to clamp the disk hanger and drive the disk hanger to rotate, and a rotation assembly for driving the drive wheel to rotate, the drive wheel is rotatably mounted on the frame, and the rotation assembly is supported on the frame.

In an optional embodiment, the rotation drive mechanism further includes an auxiliary wheel for cooperating with the drive wheel to press against the disk hanger, and the auxiliary wheel is rotatably mounted on the frame.

In an optional embodiment, the rotation assembly includes a rotation motor, a gear train connected to the drive wheel, and a chain transmission structure for connecting the gear train with the drive wheel, the drive wheel is rotatably mounted on the frame, and the rotation motor is supported on the frame.

In an optional embodiment, the vertical spray rack includes a plurality of spray pipes arranged on a vertical surface and a bracket for supporting each of the spray pipes, a plurality of nozzles are installed on each of the spray pipes, and the bracket is connected to the lift mechanism.

In an optional embodiment, each of the spray pipes is arranged vertically, and the plurality of spray pipes are arranged in a horizontal direction.

In an optional embodiment, the surface treatment device further includes a slag filter device for filtering and recovering the liquid medicine.

The beneficial effects of the surface treatment equipment provided by the embodiments of the present disclosure are: compared with the related art, in the present disclosure, a vertical spray rack is provided to achieve vertical spray. The support wheel and the rotation drive mechanism are provided to drive the disk hanger to rotate, and the lift mechanism is provided to push the vertical spray rack to move up and down. Thereby, the liquid medicine sprayed by the vertical spray rack can well cover the circuit board on the disc hanger to treat the surface of the circuit board. In addition, the circuit board can be prevented from being impacted by the side, so as to ensure the production quality of the circuit board.

### BRIEF DESCRIPTION OF THE DRAWINGS

In order to more clearly illustrate the embodiments of the present disclosure, drawings used in the embodiments will be briefly described below. Obviously, the drawings in the following description are only some embodiments of the present disclosure. It will be apparent to those skilled in the art that other figures can be obtained according to the structures shown in the drawings without creative work.

FIG. 1 is a structural schematic side view of a surface treatment device according to a first embodiment of the present disclosure.

FIG. 2 is a structural schematic front view of the surface treatment device according to the first embodiment of the present disclosure.

FIG. 3 is a structural schematic diagram of a rotation drive part of a disk hanger in the surface treatment device of FIG. 2.

FIG. 4 is a structural schematic side view of the rotation drive part of the disk hanger in FIG. 3.

FIG. 5 is a structural schematic front view of a vertical spray part of the surface treatment device in FIG. 2.

FIG. 6 is a structural schematic top view of the vertical spray part in FIG. 5.

FIG. 7 is a structural schematic left view of the vertical spray part in FIG. 5.

FIG. 8 is a structural schematic right view of the vertical spray part in FIG. 5.

FIG. 9 is a structural schematic diagram of a rotation drive part of a disk hanger in the surface treatment device according to a second embodiment of the present disclosure.

FIG. 10 is a structural schematic cross-sectional view of the rotation drive part of the disk hanger in FIG. 9.

FIG. 11 is a structural schematic side view of the surface treatment device according to a third embodiment of the present disclosure.

### DETAILED DESCRIPTION OF THE EMBODIMENTS

In order to make the technical problems to be solved by the present disclosure, technical solutions, and beneficial effects clearer, the present disclosure will be further described in detail below in conjunction with the drawings and embodiments. It should be understood that the specific embodiments described herein are only configured to explain the present disclosure, and are not intended to limit the present disclosure.

It should be noted that when an element is referred to as being “fixed to” or “provided on” another element, it can be directly on the other element or indirectly on the other element. When an element is referred to as being “connected to” another element, it can be directly connected to the other element or indirectly connected to the other element.

In the description of the present disclosure, “a plurality of” means two or more than two, unless otherwise specifically defined. The meaning of “several” is one or more than one, unless otherwise specifically defined.

In the description of the present disclosure, it should be understood that the orientation or positional relationship indicated by the terms “center”, “length”, “width”, “thickness”, “upper”, “lower”, “front”, “rear”, “left”, “right”, “vertical”, “horizontal”, “up”, “down”, “inner”, “outer” etc. are based on the orientation or positional relationship shown in the drawings, and are only for the convenience of describing the present disclosure and simplifying the description, and do not indicate or imply that the pointed device or element must have a specific orientation, be constructed and operated in a specific orientation, and therefore cannot be understood as a limitation of the present disclosure.

In the description of the present disclosure, it should be understood that unless otherwise specified and restricted, the terms “install”, “connect” and “connected” should be understood in a broad sense, for example, it can be a fixed connection, a detachable connection, or an integral connection; it can be a mechanical connection or an electrical connection; it can be directly connected, or indirectly connected through an intermediate medium; or it can be a communication between two elements or an interaction relationship between two elements. For those ordinary skilled in the art, the specific meanings of the above terms in the present disclosure can be understood according to specific circumstances.

The reference to “one embodiment”, “some embodiments” or “embodiments” described in the specification of the present disclosure means that one or more embodiments of the present disclosure include a specific feature, structure, or characteristic described in conjunction with the embodiment. Thus, the phrases “in one embodiment”, “in some embodiments”, “in another embodiments”, “in some other embodiments”, etc. appearing in this specification do not necessarily all refer to the same embodiment, but mean “one or more but not all embodiments”, unless it is specifically emphasized otherwise. In addition, in one or more embodiments, specific features, structures, or characteristics may be combined in any suitable manner.

### First Embodiment

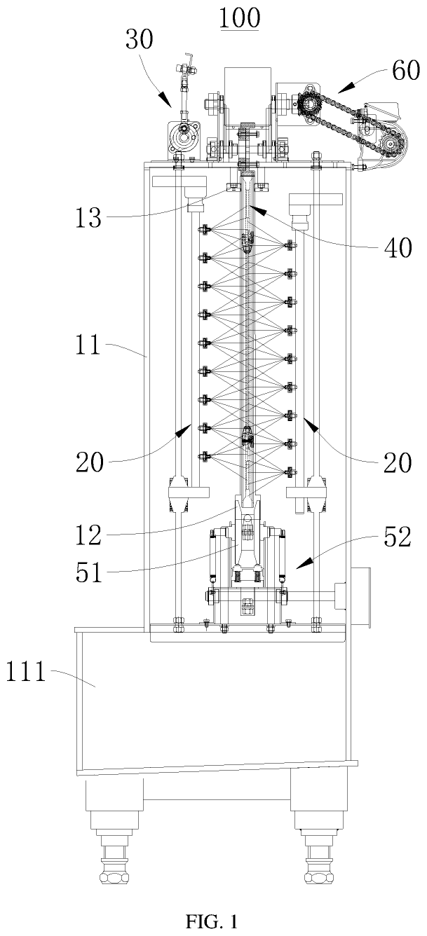

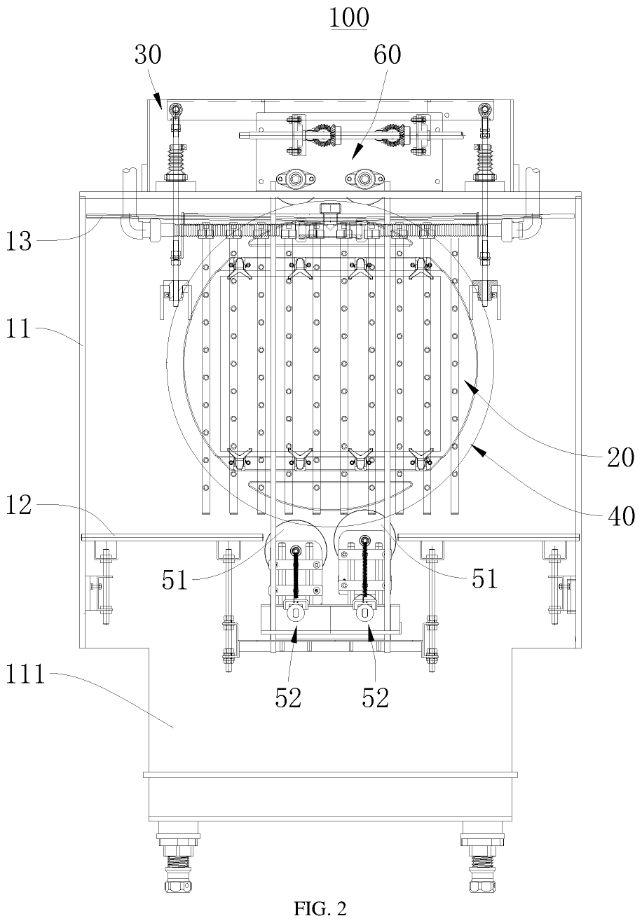

As shown in FIG. 1 and FIG. 2, a surface treatment device 100 provided in the present disclosure will now be described. The surface treatment device 100 includes a frame 11, a disc hanger 40, two support wheels 51, a rotation drive mechanism 60, a vertical spray rack 20 and a lift mechanism 30. The disc hanger 40 is configured to hold a circuit board to process the circuit board. The rotation drive mechanism 60 is supported on the frame 11, and the rotation drive mechanism 60 is configured to drive the disk hanger 40 supported on the two supporting wheels 51 to rotate. The two support wheels 51 are supported on the frame 11, and the two support wheels 51 are configured to support the disk hanger 40 such that the disk hanger 40 can rotate flexibly. The vertical spray rack 20 is configured to spray liquid medicine on the circuit board on the disk hanger 40. The vertical spray rack 20 is supported on the lift mechanism 30, such that the vertical spray rack 20 is supported through the lift mechanism 30. The lift mechanism 30 is installed on the frame 11 to support the lift mechanism 30 and the vertical spray rack 20 through the frame 11. The lift mechanism 30 drives the vertical spray rack 20 up and down, so that the sprayed liquid medicine can better cover a vertical line. The rotation drive mechanism 60 drives the disk hanger 40 to rotate, so that the liquid sprayed from the vertical spray rack 20 can cover the entire circuit board. The liquid medicine sprayed on the circuit board can be better disturbed and flow on the circuit board to process the surface of the circuit board. Since the vertical spray rack 20 moves up and down, the circuit board can be prevented from being impacted by the side, so as to ensure the production quality of the circuit board.

Compared with the related art, in the present disclosure, a vertical spray rack 20 is provided to achieve vertical spray. The support wheel 51 and the rotation drive mechanism 60 are provided to drive the disk hanger 40 to rotate, and the lift mechanism 30 is provided to push the vertical spray rack 20 to move up and down. Thereby, the liquid medicine sprayed by the vertical spray rack 20 can well cover the circuit board on the disc hanger 40 to treat the surface of the circuit board. In addition, the circuit board can be prevented from being impacted by the side, so as to ensure the production quality of the circuit board.

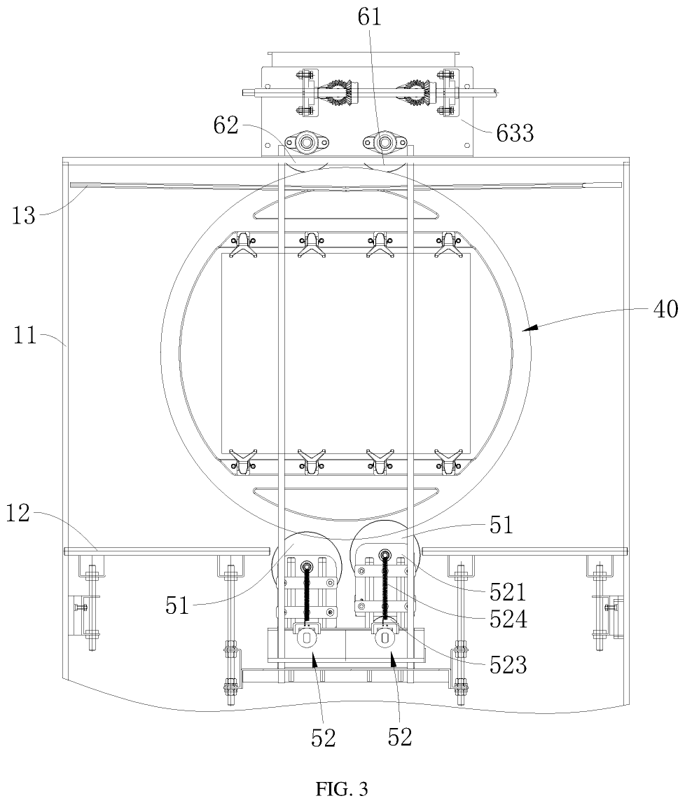

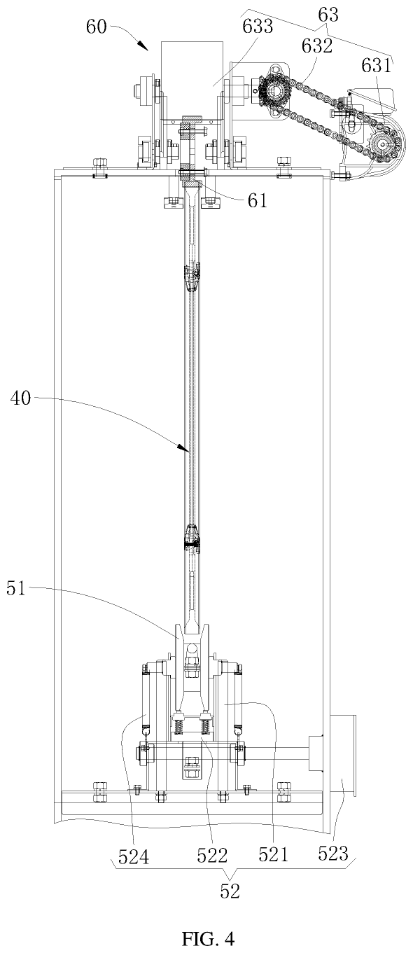

In an embodiment, as shown in FIG. 3 and FIG. 4, the surface treatment device 100 further includes a guide rail 12, a guide bar 13 and two lifters 52. The two lifters 52, the guide rail 12, and the guide bar 13 are respectively installed on the frame 11. Two support wheels 51 are respectively installed on the two lifters 52. The two support wheels 51 are driven up and down by the two lifters 52 respectively, and then the two support wheels 51 cooperate with the disc hanger 40. The disk hanger 40 can be moved to contact the rotation drive mechanism 60 so that the rotation drive mechanism 60 can drive the disk hanger 40 to rotate. The two support wheels 51 are respectively provided with guide rails 12 on both sides, and the guide rails 12 are configured to guide the movement of the disk hanger 40 to transfer the disk hanger 40. The guide bar 13 is configured to support an upper side of the disk hanger 40, so that when the disk hanger 40 rolls and is transferred on the guide rail 12, the guide bar 13 can abut against both sides of the disk hanger 40 to keep the disk hanger 40 upright, which facilitates the disk hanger 40 to roll on the guide rail 12.

In an embodiment, as shown in FIG. 3 and FIG. 4, the rotation drive mechanism 60 includes a drive wheel 61 and a rotation assembly 63. The drive wheel 61 is rotatably mounted on the frame 11, and the rotation assembly 63 is supported on the frame 11. The drive wheel 61 is configured to cooperate with the two support wheels 51 to clamp the disk hanger 40, and when the drive wheel 61 rotates, the drive wheel 61 can drive the disk hanger 40 to rotate.

In an embodiment, as shown in FIG. 3 and FIG. 4, the rotation assembly 63 includes a rotation motor 631, a gear train 633 connected with the drive wheel 61, and a chain transmission structure 632 connecting the gear train 633 and the drive wheel 61. The drive wheel 61 is rotatably mounted on the frame 11, and the rotation assembly 63 is supported on the frame 11. The use of the chain transmission structure 632 can facilitate the layout of the position of the rotation motor 631 and reduce the installation accuracy. In some embodiments, the rotation motor 631 can be directly configured to drive the drive wheel 61 to rotate. In some embodiments, a gear train 633 may be configured to connect the rotation motor 631 and the drive wheel 61 to ensure that the drive wheel 61 rotates accurately, thereby accurately positioning the disk hanger 40.

In an embodiment, as shown in FIG. 3 and FIG. 4, the rotation drive mechanism 60 further includes an auxiliary wheel 62 rotatably mounted on the frame 11. When the two support wheels 51 drive the disk hanger 40 to rise, the auxiliary wheel 62 can cooperate with the drive wheel 61 to press the disk hanger 40. The disk hanger 40 can be positioned better, and the drive wheel 61 can better press against the disk hanger 40, so that the drive wheel 61 can better drive the disk hanger 40 to rotate.

In an embodiment, as shown in FIG. 3 and FIG. 4, the auxiliary wheel 62 is connected to the gear train 633, so that the gear train 633 drives the auxiliary wheel 62 to rotate, and the auxiliary wheel 62 and the drive wheel 61 can simultaneously drive the disk hanger 40 to rotate, so as to drive the disk hanger 40 to rotate more stably.

In an embodiment, as shown in FIG. 3 and FIG. 4, the lifter 52 includes a support base 521, an eccentric cam 522 and a rotator 523. The rotator 523 is installed on the frame 11, and the support wheel 51 is rotatably installed on the corresponding support base 521. The support base 521 is slidably mounted on the frame 11 so that the support base 521 can drive the support wheel 51 to move up and down on the frame 11. The eccentric cam 522 is installed on the rotator 523, and the eccentric cam 522 is driven to rotate by the rotator 523, thereby pushing the support base 521 up and down. Using the eccentric cam 522 to rotate to push the support base 521 up and down can avoid arranging the rotator 523 directly below the support wheel 51. Furthermore, the processing liquid on the circuit board after processing can be prevented from falling on the rotator 523, and the rotator 523 can be protected. In an embodiment, the rotator 523 may use a rotation motor 631, a rotation cylinder, or the like.

In an embodiment, the lifter 52 further includes an elastic puller 524 for pulling the support base 521 down. An upper end of the elastic puller 524 is connected to the support base 521, and a lower end of the elastic puller 524 is connected to the frame 11. The support base 521 resists the eccentric cam 522 through the elastic puller 524, which is convenient for the eccentric cam 522 to push the support base 521 up and down. In an embodiment, the elastic puller 524 is a spring. In some embodiments, the elastic puller 524 may be an elastic cord.

In some embodiments, the lifter 52 may include a support rod for supporting the support wheel 51 and a lift structure for driving the support rod up and down. The lift structure can be an air cylinder, a screw nut mechanism, etc. The lift structure can be installed on the top of the frame 11, and it can also prevent the processing liquid on the circuit board from falling on the lift structure.

The loading and unloading process of the disk hanger 40 in the embodiment of the present disclosure is as follows:

As shown in FIG. 2 and FIG. 3, the disk hanger 40 rolls and transmits on the guide rail 12. A lifter 52 located downstream in the transmission direction of the guide rail 12 pushes the corresponding support wheel 51 up to stop the disk hanger 40. When the disc hanger 40 rolls between the two support wheels 51, the other lifter 52 pushes the support wheel 51 located upstream in the transmission direction of the guide rail 12 to rise, so that the two support wheels 51 cooperate to push the disc hanger 40 up, so that the disc hanger 40 resists the drive wheel 61 and the auxiliary wheel 62. The rotation assembly 63 drives the drive wheel 61 to rotate to drive the disk hanger 40 to rotate. The lift mechanism 30 drives the vertical spray rack 20 to move up and down, and the vertical spray rack 20 sprays the liquid medicine on the circuit board on the disk hanger 40 to perform surface treatment on the circuit board. When the surface treatment on the circuit board is completed, a lifter 52 located downstream in the transmission direction of the guide rail 12 pushes the corresponding support wheel 51 down, then a lifter 52 located upstream in the transmission direction of the guide rail 12 pushes the corresponding support wheel 51 down. When the lifter 52 located upstream in the transmission direction of the guide rail 12 pushes the corresponding support wheel 51 down, the disk hanger 40 is separated from the drive wheel 61, and rolls forward under the guide rail 12 to roll and transfer to the next station.

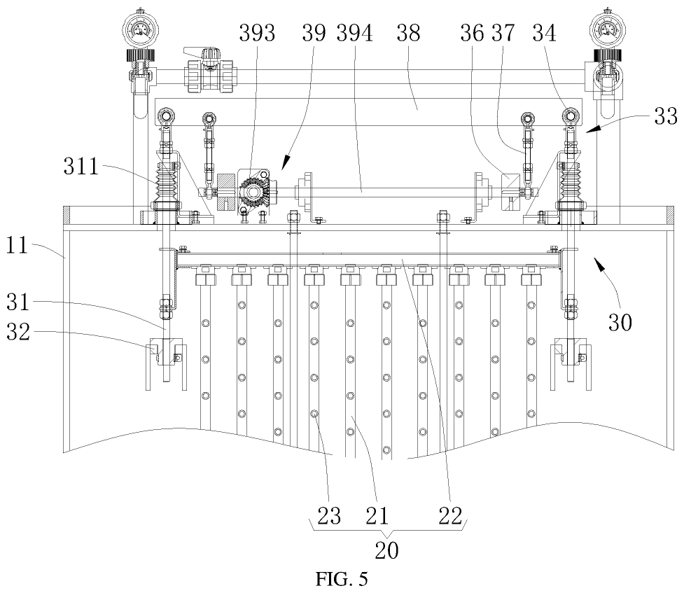

In an embodiment, as shown in FIG. 1 and FIG. 5, there are two vertical spray racks 20, and the two vertical spray racks 20 are arranged side by side on both sides of the disk hanger 40. Two vertical spray racks 20 are provided to spray the liquid medicine on both sides of the circuit board at the same time, so as to better perform surface treatment on the circuit board and improve efficiency. Of course, in some embodiments, only one vertical spray rack 20 may be provided to spray one side of the circuit board.

In an embodiment, as shown in FIG. 5, the vertical spray rack 20 includes a plurality of spray pipes 21 and a bracket 22. Each of the spray pipes 21 is installed on the bracket 22, and each of the spray pipes 21 is supported by the bracket 22. A plurality of spray pipes 21 are arranged on a vertical surface, and a plurality of nozzles 23 are installed on each of the spray pipes 21, so that the plurality of nozzles 23 are arranged on the vertical surface for vertical spraying. The bracket 22 is connected to the lift mechanism 30 to drive the bracket 22 up and down through the lift mechanism 30, thereby driving the spray pipes 21 and the nozzles 23 on them to move up and down. In some embodiments, a hollow plate body can also be used, the nozzle 23 is installed on the plate body, and the plate body is vertically arranged to form a vertical spray rack 20.

In an embodiment, each of the spray pipes 21 is arranged vertically, and a plurality of spray pipes 21 are arranged in a horizontal direction, so as to realize the arrangement of each of the nozzles 23 on a vertical surface. Of course, in some embodiments, each of the spray pipes 21 can also be arranged horizontally, and a plurality of spray pipes 21 are arranged in a vertical direction, or each of the nozzles 23 can be arranged on a vertical surface.

In an embodiment, the lift mechanism 30 may be a linear movement mechanism such as a screw nut mechanism, a linear motor, an air cylinder, etc., to directly drive the vertical spray rack 20 up and down.

In an embodiment, as shown in FIG. 5 to FIG. 7, the lift mechanism 30 includes lift rods 31, a guide base 32 and a lift drive mechanism 33. Each vertical spray rack 20 is respectively connected with a lift rod 31 to support the corresponding vertical spray rack 20 through the lift rod 31. The lift rod 31 is slidably mounted on the frame 11, and the guide base 32 and the lift rod 31 are in a one-to-one correspondence, so as to guide the lift rod 31 to move up and down through the guide base 32. The guide base 32 can be a guide sleeve, a guide ring, etc. The guide base 32 is sleeved on the lift rod 31 to guide the lift rod 31 up and down, and each guide base 32 is installed on the frame 11. The lift drive mechanism 33 is installed on the frame 11, and the lift rod 31 is driven to move up and down through the lift drive mechanism 33 to drive the corresponding vertical spray rack 20 to move up and down. Setting the lift rod 31 can better guide the vertical spray rack 20 to move up and down, and ensure the vertical spray rack 20 to lift smoothly. In some embodiments, the lift mechanism 30 may be a linear movement mechanism such as a screw nut mechanism, a linear motor, and an air cylinder to directly drive the lift rod 31 to move up and down.

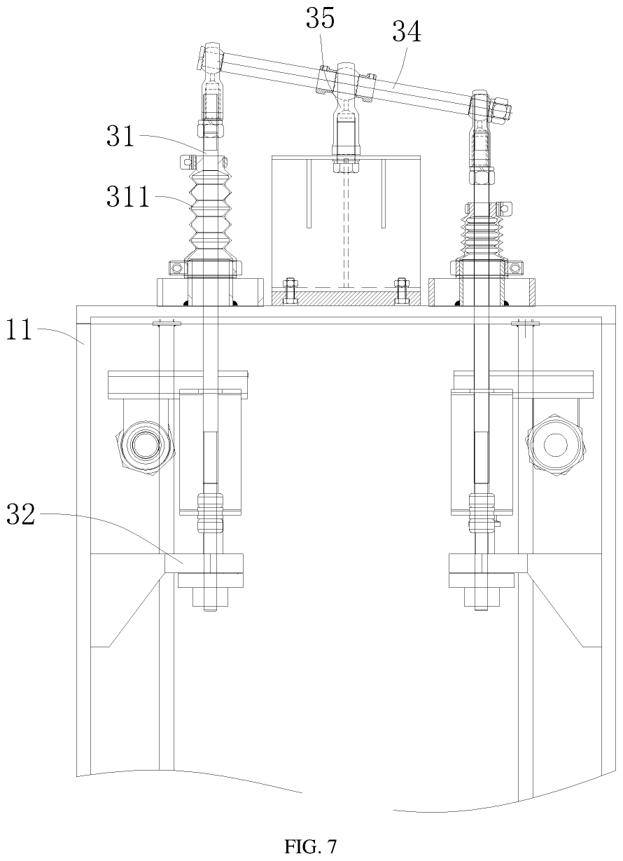

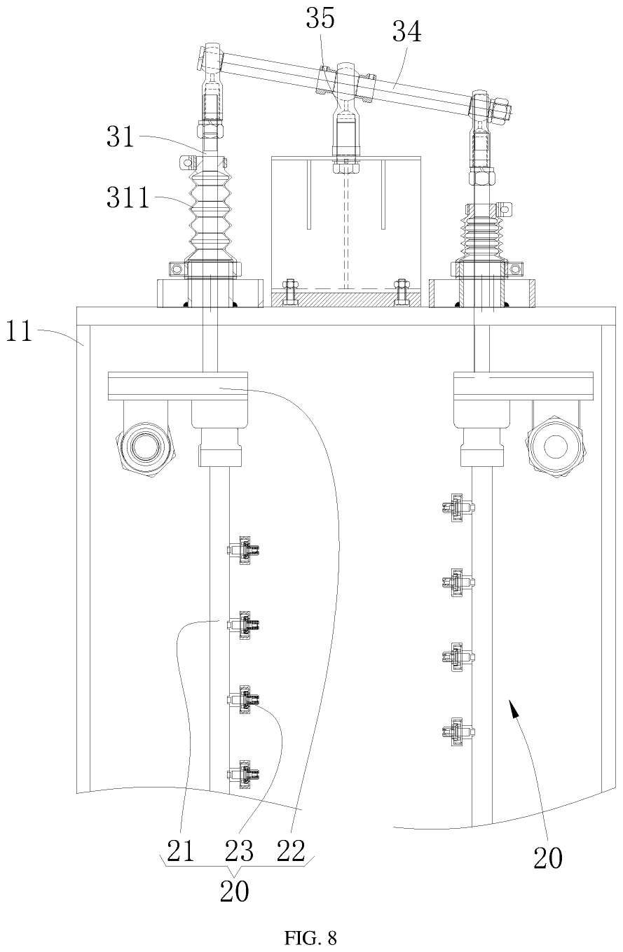

In an embodiment, as shown in FIG. 5, FIG. 7 and FIG. 8, the lift mechanism 30 further includes an elastic ejector 311. The lift rods 31 are respectively installed in the elastic ejector 311. An upper end of the elastic ejector 311 is fixedly connected to the lifting rod 31, a lower end of the elastic ejector 311 is supported on the frame 11, and the elastic ejector 311 is configured to elastically push the corresponding lift rod 31 upward. The elastic ejector 311 elastically pushes the lift rod 31 upwards, which can offset part of the gravity of the vertical spray rack 20 and the lift rod 31 to facilitate the lift drive mechanism 33 to flexibly push the lift rod 31 and the corresponding vertical spray rack 20 to move up and down.

In an embodiment, the elastic ejector 311 is an elastic telescopic tube, such as a corrugated tube with elastic telescoping performance, or an elastic telescopic rubber tube. In some embodiments, the elastic ejector 311 may also be a spring, or an elastic rubber cylinder with a spring skeleton.

In an embodiment, as shown in FIG. 5 to FIG. 7, the lift drive mechanism 33 includes a push rod 34, a support 35, a rocker 37, an eccentric wheel 36 and a rotation drive assembly 39. The rotation drive assembly 39 is mounted on the frame 11, the support 35 is mounted on the frame 11, and a middle of the push rod 34 is hinged to the support 35 and connected with the support 35. Both ends of the push rod 34 are respectively hinged with the lifting rods 31 corresponding to the two vertical spray racks 20, and the middle of the push rod 34 is hinged with the support 35, so that the push rod 34 forms a seesaw structure. The rocker 37 is mounted on the eccentric wheel 36. Rotation of the eccentric wheel 36 drives the rocker 37 to swing, and the rocker 37 is connected to one end of the push rod 34 to drive one end of the push rod 34 up and down, and at the same time to drive the other end of the push rod 34 up and down. In this way, the lift rods 31 at both ends of the push rod 34 are moved up and down synchronously in the opposite direction, thereby driving the two vertical spray racks 20 to move up and down.

In an embodiment, the rotation drive assembly 39 includes a rotation shaft 394, a drive shaft 392, a direction changer 393 and a lift motor 391. The eccentric wheel 36 is mounted on the rotation shaft 394, and is supported by the rotation shaft 394 and drives the eccentric wheel 36 to rotate. The direction changer 393 connects the drive shaft 392 and the rotation shaft 394. The lift motor 391 is connected to the drive shaft 392 to drive the drive shaft 392 to rotate, and then the rotation shaft 394 is driven to rotate through the direction changer 393, which in turn drives the eccentric wheel 36 to rotate. This structure can facilitate the position layout of the lift motor 391. The direction changer 393 may use a bevel gear structure or a worm gear structure or the like. In some embodiments, it is also possible to directly use the lift motor 391 to drive the eccentric wheel 36 to rotate, or to use the lift motor 391 to drive the rotation shaft 394 to rotate.

In an embodiment, the lift drive mechanism 33 includes a plurality of push rods 34 and a plurality of supports 35. The support 35 and the push rod 34 are in one-to-one correspondence. Both ends of each push rod 34 are respectively hinged with lift rods 31. The lift rods 31 at both ends of each push rod 34 are respectively connected to two vertical spray racks 20 to more stably support each vertical spray rack 20 and smoothly drive the vertical spray racks 20 to move up and down. The lift drive mechanism 33 further includes a connection rod 38, one end of each push rod 34 is hinged with the connection rod 38, and the rocker 37 is hinged with the connection rod 38. Thus, the connection rod 38 is driven up and down by the rocker 37, and the push rods 34 are driven to swing synchronously, so as to drive the vertical spray racks 20 to move up and down smoothly.

In some embodiments, a plurality of lift rods 31 are connected to each vertical spray rack 20. The lift drive mechanism 33 further includes a connection rod 38 respectively connected to a plurality of lift rods 31 corresponding to each vertical spray rack 20, and both ends of the push rod 34 are hinged to the two connection rods 38 respectively. This structure can also drive the lift rods 31 corresponding to the vertical spray racks 20 up and down synchronously, so as to ensure the vertical spray racks 20 up and down smoothly. In addition, in some embodiments, only one push rod 34 may be provided to simplify the structure.

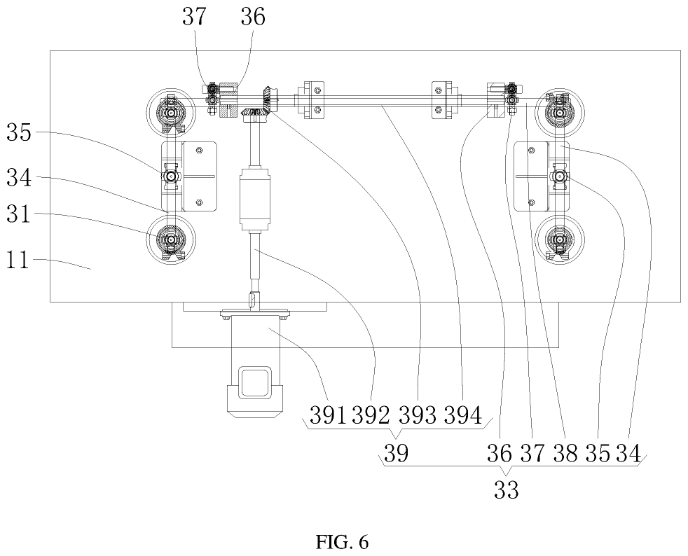

In an embodiment, as shown in FIG. 5 and FIG. 6, a plurality of eccentric wheels 36 are mounted on the rotation shaft 394. Each eccentric wheel 36 is respectively provided with a rocker 37, and each rocker 37 is hinged with the connection rod 38, so as to more smoothly drive the connection rod 38 to move up and down. Of course, in some embodiments, the rocker 37 and the eccentric wheel 36 may both be one.

In one embodiment, as shown in FIG. 1, a lower end of the frame 11 is also provided with a collection tank 111 to collect the liquid sprayed by the vertical spray rack 20 to prevent pollution, and the liquid can be recovered and processed.

The surface treatment device 100 of the embodiment of the present disclosure may be an etching device for etching the circuit board, may be a cleaning device for cleaning the circuit board, or may be a film removal device for removing the film of the circuit board. Of course, when spraying is required in the circuit board treatment process, the surface treatment device 100 of the present disclosure can also be used.

### Second Embodiment

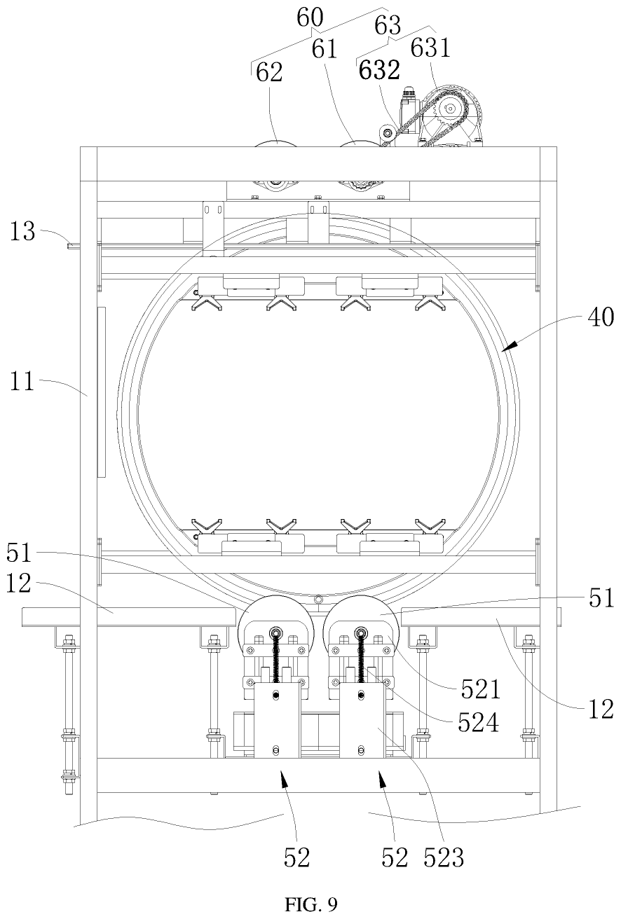

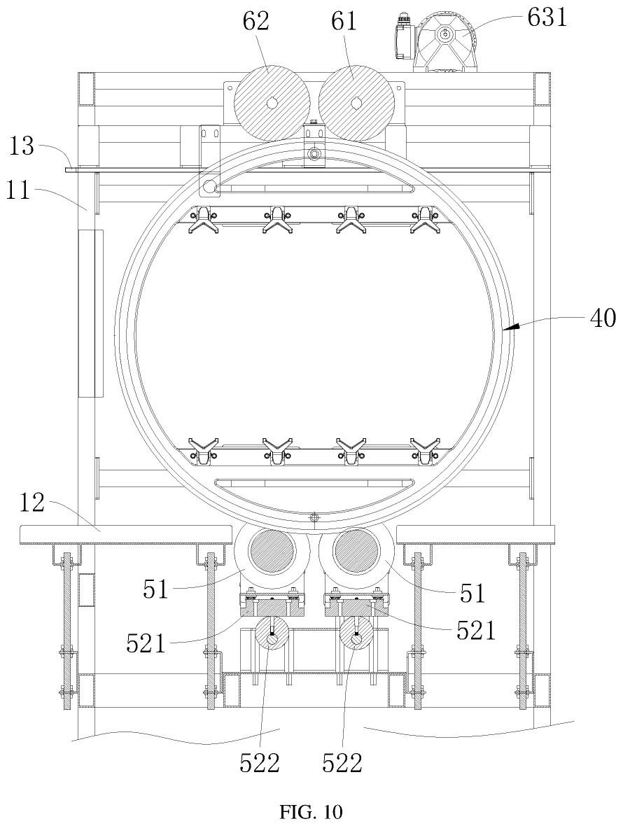

As shown in FIG. 9 and FIG. 10, the difference between the surface treatment device 100 of this embodiment and the surface treatment device 100 of the first embodiment is as follows.

In this embodiment, the rotation assembly 63 includes a rotation motor 631 and a chain transmission structure 632 connecting the rotation motor 631 and the drive wheel 61. The use of the chain transmission structure 632 can facilitate the layout of the position of the rotation motor 631 and reduce the installation accuracy. Compared with the first embodiment, this structure simplifies the structure of the rotation assembly 63.

In an embodiment, the rotation drive mechanism of the disk hanger 40 further includes an auxiliary wheel 62. The auxiliary wheel 62 is rotatably mounted on the frame 11. When the two support wheels 51 drive the disk hanger 40 to rise, the auxiliary wheel 62 can cooperate with the drive wheel 61 to press the disk hanger 40 to better position the disk hanger 40, thereby making the drive wheel 61 better press against the disc hanger 40, so that when the drive wheel 61 drives the disc hanger 40 to rotate, the auxiliary wheel 62 will rotate with the disk hanger 40 to ensure the smooth and flexible rotation of the disk hanger 40; in addition, compared with the first embodiment, this structure simplifies the structure, facilitates assembly and reduces costs.

The other structures of the surface treatment device 100 of this embodiment are the same as the other structures of the surface treatment device 100 of the first embodiment, and will not be repeated here.

### Third Embodiment

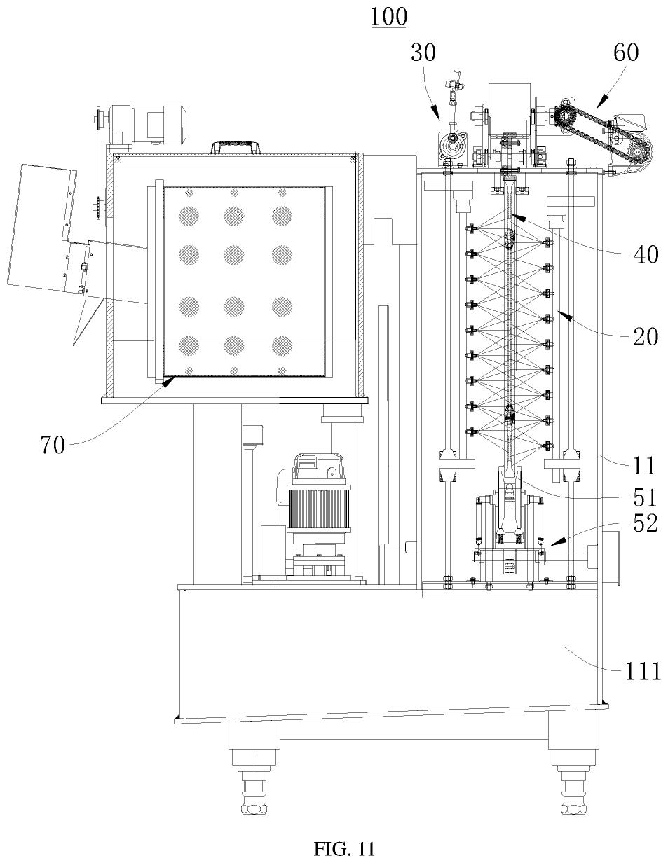

As shown in FIG. 11, the difference between the surface treatment device 100 of this embodiment and the surface treatment device 100 of the first embodiment is as follows.

In this embodiment, the surface treatment device 100 further includes a slag filter device 70, which can filter the recovered liquid medicine to filter out the slag, impurities, etc. in the recovered liquid medicine. The surface treatment device 100 can be used as a de-filming device for circuit board treatment, and the slag filter device 70 can filter the slag film in the liquid medicine.

The other structures of the surface treatment device 100 of this embodiment are the same as the other structures of the surface treatment device 100 of the first embodiment, and will not be repeated here.

The above are only optional embodiments of the present disclosure, and are not intended to limit the present disclosure. Any modification, equivalent replacement and improvement made within the spirit and principle of the present disclosure shall be included in the protection scope of the present disclosure.

What is claimed is:

1. A surface treatment device, comprising:
a frame;
a disc hanger for holding a circuit board;
two support wheels, supported on the frame, for supporting the disk hanger;
a rotation drive mechanism, supported on the frame, for driving the disk hanger supported on the two support wheels to rotate;
a vertical spray rack for spraying liquid medicine on the circuit board on the disk hanger; and
a lift mechanism, installed on the frame, for driving the vertical spray rack up and down,
wherein the vertical spray rack is installed on the lift mechanism.

2. The surface treatment device of claim 1, wherein:
the surface treatment device comprises two vertical spray racks, the two vertical spray racks are provided side by side on both sides of the disk hanger;
the lift mechanism comprises lift rods connected to the two vertical spray racks respectively, a guide base for guiding the lift rod up and down, and a lift drive mechanism for driving the lift rod up and down; and
the lift drive mechanism is installed on the frame, the guide base is installed on the frame, and the lift rod is slidably installed on the frame.

3. The surface treatment device of claim 2, wherein:
the lift drive mechanism comprises a push rod, a support for supporting a middle of the push rod, a rocker for driving one end of the push rod up and down, an eccentric wheel for driving the rocker to swing and a rotation drive assembly for driving the eccentric wheel to rotate; and
both ends of the push rod are hinged and connected to the lift rods corresponding to the vertical spray racks, the rotation drive assembly is installed on the frame, the support is installed on the frame, and the middle of the push rod is hinged and connected to the support.

4. The surface treatment device of claim 3, wherein:
the rotation drive assembly comprises a rotation shaft for supporting the eccentric wheel, a drive shaft for driving the rotation shaft to rotate, a direction changer connecting the drive shaft with the rotation shaft, and a lift motor for driving the drive shaft to rotate; and
the lift motor is installed on the frame, the drive shaft and the rotation shaft are rotatably installed on the frame.

5. The surface treatment device of claim 3, wherein:
the lift drive mechanism comprises a plurality of push rods and a plurality of supports for supporting the push rods;
both ends of each of the push rods are hinged with the lift rods, and the lift rods at both ends of each of the push rods are respectively connected to the two vertical spray racks; and
the lift drive mechanism further comprises a connection rod, one end of each of the push rods is hinged with the connection rod, and the rocker is hinged with the connection rod.

6. The surface treatment device of claim 2, wherein:
the lift mechanism further comprises an elastic pusher for elastically pushing a corresponding lift rod upward; and
an upper end of the elastic pusher is fixedly connected to the corresponding lift rod, and a lower end of the elastic pusher is supported on the frame.

7. The surface treatment device of claim 1, further comprising:
guide rails respectively provided on both sides of the two support wheels, for guiding transmission of the disk hanger;
a guide bar installed on the frame for supporting an upper side of the disk hanger; and
two lifters installed on the frame for driving the two support wheels up and down respectively;
wherein the two support wheels are respectively installed on the two lifters.

8. The surface treatment device of claim 7, wherein:
each of the two lifters comprises a support base slidably mounted on the frame, an eccentric cam for pushing the support base up and down, and a rotator for driving the eccentric cam to rotate; and
the rotator is installed on the frame, and each of the support wheels is rotatably installed on the corresponding support base.

9. The surface treatment device of claim 8, wherein each of the two lifters further comprises an elastic puller for pulling the support base down, an upper end of the elastic puller is connected to the support base, and a lower end of the elastic puller is connected to the frame.

10. The surface treatment device of claim 1, wherein the rotation drive mechanism comprises a drive wheel for cooperating with the two support wheels to clamp the disk hanger and drive the disk hanger to rotate, and a rotation assembly for driving the drive wheel to rotate, the drive wheel is rotatably mounted on the frame, and the rotation assembly is supported on the frame.

11. The surface treatment device of claim 10, wherein the rotation drive mechanism further comprises an auxiliary wheel for cooperating with the drive wheel to press against the disk hanger, and the auxiliary wheel is rotatably mounted on the frame.

12. The surface treatment device of claim 10, wherein the rotation assembly comprises a rotation motor, a gear train connected to the drive wheel, and a chain transmission structure for connecting the gear train with the drive wheel, the drive wheel is rotatably mounted on the frame, and the rotation motor is supported on the frame.

13. The surface treatment device of claim 1, wherein the vertical spray rack comprises a plurality of spray pipes arranged on a vertical surface and a bracket for supporting each of the spray pipes, a plurality of nozzles are installed on each of the spray pipes, and the bracket is connected to the lift mechanism.

14. The surface treatment device of claim 13, wherein each of the spray pipes is arranged vertically, and the plurality of spray pipes are arranged in a horizontal direction.

15. The surface treatment device of claim 1, further comprising a slag filter device for filtering and recovering the liquid medicine.
